(19) United States
(12) Patent Application Publication
(10) Pub. No.: US 2020/0220503 A1
(43) Pub. Date: Jul. 9, 2020

(54) LOW NOISE AMPLIFIER AND SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Toshiki Seshita, Kawasaki Kanagawa (JP); Yasuhiko Kuriyama, Yokohama Kanagawa (JP)

(21) Appl. No.: 16/569,312

(22) Filed: Sep. 12, 2019

(30) Foreign Application Priority Data
Jan. 4, 2019 (JP) 2019-000276

(51) Int. Cl. H03F 1/26; H03F 3/195; H03F 1/02; H04B 1/48; H04B 1/00

(52) U.S. Cl. CPC H03F 1/26; H03F 3/195; H03F 1/0211; H04B 1/48; H03F 2200/267; H03F 2200/294; H03F 2200/249; H03F 2200/451; H04B 1/006

(57) ABSTRACT

A low noise amplifier has a first transistor that amplifies a high frequency input signal, a second transistor that further amplifies the amplified signal to generate an output signal, a first inductor connected between the source of the first transistor and a first reference potential node, a third transistor that is connected between the source of the first transistor and the first inductor, a first capacitor and a first resistor connected in series between a drain of the second transistor and an output node of the low noise amplifier, a second resistor and a third resistor connected in series between a gate of the third transistor and a second reference potential node, and a charge pump circuit that sets a potential of a connection node between the second resistor and the third resistor to a potential lower than a potential of the first reference potential node in the second mode.

### CROSS REFERENCE TO RELATED APPLICATIONS

This application is based upon and claims the benefit of priority from the prior Japanese Patent Application No. 2019-276, filed on Jan. 4, 2019, the entire contents of which are incorporated herein by reference.

### FIELD

An embodiment of the present invention relates to a low noise amplifier and a semiconductor device.

### BACKGROUND

In recent years, a research to replace a process of manufacturing a low noise amplifier (LNA) from a SiGe bipolar process (hereinafter, referred to as a SiGe process) with a silicon on insulator (SOI) complementary metal oxide semiconductor (CMOS) process (hereinafter, referred to as an SOI process) has been conducted. The SOI process is lower in terms of cost than the SiGe process, and since parasitic capacitance of a metal oxide semiconductor (MOS) transistor formed by the SOI process is small, power loss of a high frequency signal is small. Therefore, when the SOI process is used, a high frequency switch and a low noise amplifier can be formed on the same SOI substrate without deteriorating the electrical characteristics, such that they can be realized in a single chip and integration can be achieved.

The LNA is necessary when a signal strength of a received high frequency signal (hereinafter, referred to as a high frequency input signal) is small, but when the signal strength of the high frequency input signal is sufficiently large, it is not necessary to amplify the high frequency input signal by the LNA. Therefore, a low noise amplifier capable of choosing whether to amplify the high frequency input signal by the LNA or cause the high frequency input signal to bypass the LNA has been proposed.

In a case of providing a bypass signal path through which the high frequency input signal bypasses the LNA, it is preferable to cause the high frequency input signal to bypass the LNA without generating signal loss as much as possible. Higher linearity is also required. One of the measures to evaluate the linearity is 1 dB input compression point (IP1 dB). IP1 dB represents an input power level at which a gain is decreased by 1 dB, and when the high frequency input signal bypasses the LNA, it is preferable that IP1 dB be as large as possible.

### BRIEF DESCRIPTION OF THE DRAWINGS

FIG. 1 is a circuit diagram of a low noise amplifier (LNA) according to a first embodiment;

FIG. 2 is a table illustrating a power supply voltage, a first bias voltage, a second bias voltage, and a bypass signal in a gain mode and a bypass mode;

FIGS. 3A and 3B are views illustrating small signal characteristics in the gain mode of the LNA of FIG. 1;

FIG. 4 is a graph illustrating large signal characteristics in the gain mode of the LNA of FIG. 1;

FIGS. 5A and 5B are views illustrating small signal characteristics in the bypass mode of the LNA of FIG. 1;

FIG. 6 is a circuit diagram of an LNA according to a comparative example;

FIG. 7 is a graph illustrating a comparison result between large signal characteristics in the bypass mode of the LNAs of FIGS. 1 and 6;

FIG. 8 is a circuit diagram of an LNA according to a second embodiment;

FIGS. 9A and 9B are views illustrating small signal characteristics in a gain mode of the LNA of FIG. 8;

FIG. 10 is a graph illustrating large signal characteristics in the gain mode of the LNA of FIG. 8;

FIGS. 11A and 11B are views illustrating small signal characteristics in a bypass mode of the LNA of FIG. 8;

FIG. 12 is a graph illustrating a comparison result among large signal characteristics in the bypass mode of each LNA of FIGS. 1, 6, and 8;

FIG. 13 is a circuit diagram of an LNA according to a modified example of FIG. 8;

FIG. 14 is a circuit diagram of an LNA according to a third embodiment;

FIG. 15 is a circuit diagram of an LNA according to a comparative example of FIG. 14;

FIG. 16 is a graph illustrating simulation results of the LNAs of FIGS. 14 and 15;

FIG. 17 is a block diagram illustrating a schematic configuration of a wireless device in which the LNA or high frequency amplifier according to the first to third embodiments is embedded; and

FIG. 18 is a block diagram illustrating a schematic configuration of a wireless device corresponding to carrier aggregation.

### DETAILED DESCRIPTION

According to one embodiment, a low noise amplifier has:

a first transistor that amplifies a high frequency input signal and has a grounded source;

a second transistor that further amplifies the signal amplified by the first transistor to generate an output signal and has a grounded gate;

a first inductor that is connected between the source of the first transistor and a first reference potential node;

a third transistor that is connected between the source of the first transistor and the first inductor, is turned on in a first mode, and is turned off in a second mode;

a first capacitor and a first resistor that are connected to each other in series between a drain of the second transistor and an output node of the low noise amplifier;

a second resistor and a third resistor that are connected to each other in series between a gate of the third transistor and a second reference potential node; and

a charge pump circuit that sets a potential of a connection node between the second resistor and the third resistor to a potential lower than a potential of the first reference potential node in the second mode.

Hereinafter, embodiments will be described with reference to the drawings. It should be noted that in the present specification and the accompanying drawings, some components are omitted, changed or simplified for the purpose of ease of understanding and convenience of illustration, but technical contents that can expect similar functions are also interpreted to be included in the present embodiment. Further, in the accompanying drawings of the present specification, for the purpose of ease of understanding and convenience of illustration, appropriate scales, vertical and horizontal dimensional ratios, and the like, are changed and exaggerated.

### First Embodiment

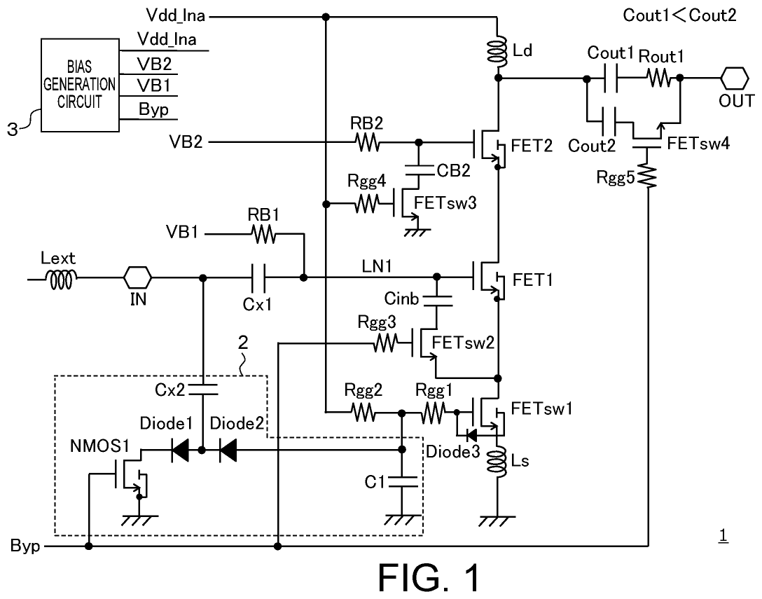

FIG. 1 is a circuit diagram of a low noise amplifier (hereinafter, referred to as an LNA) 1 according to a first embodiment. The LNA 1 of FIG. 1 can be disposed on, for example, a silicon on insulator (SOI) substrate. In addition, peripheral circuits of the LNA 1, for example, an antenna switch and the LNA 1 may be disposed on the same SOI substrate.

The LNA 1 of FIG. 1 is used in, for example, a wireless device such as a mobile phone or a smartphone, but there is no limitation on a use or a mounting place of the LNA 1. The LNA 1 of FIG. 1 has a gain mode (first mode) for amplifying a high frequency input signal and a bypass mode (second mode) for causing the high frequency input signal to bypass the LNA 1 without amplifying the high frequency input signal.

The LNA 1 of FIG. 1 includes a first transistor FET1 with a grounded source, a second transistor FET2 with a grounded gate, a first inductor Ls, a second inductor Ld, a third transistor FETsw1, a first capacitor Cout1 and a first resistor Rout1, a second capacitor Cinb, a fourth transistor FETsw2, a third capacitor CB2, a fifth transistor FETsw3, a second resistor Rgg1 and a third resistor Rgg2, a charge pump circuit 2, a fourth capacitor Cout2, a sixth transistor FETsw4, and a bias generation circuit 3.

All of the first to fourth transistors FET1, FET2, FETsw1, and FETsw2 are n-channel metal oxide semiconductor (NMOS) transistors. An input signal path LN1 is connected to a gate of the first transistor FET1. A first node IN to which a high frequency input signal is input and a fifth capacitor Cx1 are connected to each other on the input signal path LN1. In addition, an external inductor Lext is connected to the first node IN, and the high frequency input signal is input to the first node IN through the external inductor Lext. A first bias voltage VB1 is supplied to the input signal path LN1 through a fourth resistor RB1. The first bias voltage VB1 is generated by the bias generation circuit 3.

The first transistor FET1 is a source-grounded transistor having inductive source degeneration by the first inductor Ls. The second capacitor Cinb and the fourth transistor FETsw2 are connected to each other in series between the gate and the source of the first transistor FET1. A bypass signal Byp is input to a gate of the fourth transistor FETsw2 through a fifth resistor Rgg3. The bypass signal Byp is a signal that becomes high in the bypass mode.

The second transistor FET2 is cascode-connected to the first transistor FET1. More specifically, a drain of the first transistor FET1 is connected to a source of the second transistor FET2. One end of the second inductor Ld is connected to a drain of the second transistor FET2. A power supply voltage Vdd_Ina node (second reference potential node) is connected to the other end of the second inductor Ld.

A second bias voltage VB2 is supplied to a gate of the second transistor FET2 through a sixth resistor RB2. The second bias voltage VB2 is generated by the bias generation circuit 3.

The third capacitor CB2 and the fifth transistor FETsw3 are connected to each other in series between the gate of the second transistor FET2 and a ground node (first reference potential node). The power supply voltage Vdd_Ina node is connected to a gate of the fifth transistor FETsw3 through a seventh resistor Rgg4. In the bypass mode, the fifth transistor FETsw3 is in a turn-off state, such that the third capacitor CB2 is invalidated. Therefore, in the bypass mode, the second transistor FET2 functions as a switch field effect transistor (FET) in a turn-on state. Here, the switch FET is an FET having a gate to which a turn-on voltage is applied through a resistor having high resistance.

The first capacitor Cout1 and the first resistor Rout1 are connected to each other in series between the drain of the second transistor FET2 and an output node OUT of the LNA 1 of FIG. 1. In the LNA 1 of FIG. 1, a resistor is not connected to the second inductor Ld in parallel, and gain adjustment is performed by the first resistor Rout1. Therefore, in the bypass mode, there is no possibility that a high frequency signal will be leaked through the resistor connected to the second inductor Ld in parallel.

The fourth capacitor Cout2 and the sixth transistor FETsw4 are connected to each other in series and to the first capacitor Cout1 and the first resistor Rout1 in parallel. A bypass signal Byp is input to a gate of the sixth transistor FETsw4 through an eighth resistor Rgg5. The fourth capacitor Cout2 has capacitance larger than that of the first capacitor Cout1. For example, the first capacitor Cout1 has capacitance of 1 pF or less, while the fourth capacitor Cout2 has a large capacitance of 10 pF. In the bypass mode, the sixth transistor FETsw4 is turned on, such that the fourth capacitor Cout2 becomes valid, and a high frequency signal passes through the fourth capacitor Cout2 and is then output from a second node OUT. By setting capacitance of the fourth capacitor Cout2 to a sufficiently large value, it is possible to improve a gain and S22 in the bypass mode.

The third transistor FETsw1 is cascode-connected to the first transistor FET1. More specifically, a drain of the third transistor FETsw1 is connected to the source of the first transistor FET1. A source of the third transistor FETsw1 is connected to one end of the first inductor Ls, and the other end of the first inductor Ls is connected to a ground node. The second resistor Rgg1 and the third resistor Rgg2 are connected to each other in series between a gate of the third transistor FETsw1 and the power supply voltage Vdd_Ina node.

A first diode Diode3 is connected between a body and the gate of the third transistor FETsw1. An anode of the first diode Diode3 is connected to the body of the third transistor FETsw1, and a cathode of the first diode Diode3 is connected to the gate of the third transistor FETsw1. The first diode Diode3 is a PN junction diode, and can improve a drain withstand voltage when a gate potential of the third transistor FETsw1 is a negative potential.

The charge pump circuit 2 performs a charge pump operation using a high frequency input signal as a clock signal. The charge pump circuit 2 performs the charge pump operation in the bypass mode and stops the charge pump operation in the gain mode. An output node of the charge pump circuit 2 is connected to a connection node between the second resistor Rgg1 and the third resistor Rgg2.

More specifically, the charge pump circuit 2 includes a sixth capacitor Cx2, a seventh capacitor C1, a second diode Diode2, a third diode Diode1, and a seventh transistor NMOS1. One end of the sixth capacitor Cx2 is electrically connected to the first node IN of the high frequency input signal. The other end of the sixth capacitor Cx2 is connected to a cathode of the second diode Diode2 and an anode of the third diode Diode1. A drain of the seventh transistor NMOS1 is connected to the cathode of the third diode Diode1, and a source of the seventh transistor NMOS1 is connected to a ground node. A bypass signal Byp is input to a gate of the seventh transistor NMOS1. The seventh transistor NMOS1 is turned on when the bypass signal Byp is high (that is, in the bypass mode). The charge pump circuit 2 performs the charge pump operation when the seventh transistor NMOS1 is turned on (that is, in the bypass mode), and stops the charge pump operation in the gain mode. One end of the seventh capacitor C1 is connected to an anode of the second diode Diode2 and the connection node between the third resistor Rgg2 and the second resistor Rgg1.

When the high frequency input signal is increased to a positive side, a potential of a lower electrode of the sixth capacitor Cx2 becomes higher, such that a current flows from the lower electrode of the sixth capacitor Cx2 to the ground node through the third diode Diode1 and the seventh transistor NMOS1. When the high frequency input signal is increased to a negative side, a potential of the lower electrode of the sixth capacitor Cx2 becomes a negative potential, such that a current flows from the power supply voltage Vdd_Ina node to the lower electrode of the sixth capacitor Cx2 through the third resistor Rgg2 and the second diode Diode2. In the bypass mode, since the power supply voltage Vdd_Ina node is at a ground potential, a potential of the connection node between the second resistor Rgg1 and the third resistor Rgg2 becomes a negative potential by the current flowing from the power supply voltage Vdd_Ina node to the lower electrode of the sixth capacitor Cx2 through the third resistor Rgg2 and the second diode Diode2. When the potential of the connection node between the second resistor Rgg1 and the third resistor Rgg2 is the negative potential, a potential of the gate of the third transistor FETsw1 also becomes a negative potential, and the third transistor FETsw1 can thus be certainly turned off. That is, by providing the charge pump circuit 2, a turn-off withstand voltage of the third transistor FETsw1 can be improved and IP1 dB in the bypass mode can be improved.

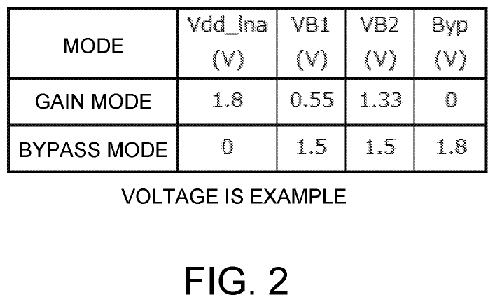

FIG. 2 is a table illustrating a power supply voltage Vdd_lna, the first bias voltage VB1, the second bias voltage VB2, and the bypass signal Byp in the gain mode and the bypass mode. In addition, a voltage value of FIG. 2 is only an example. Each voltage and signal of FIG. 2 are generated by, for example, the bias generation circuit 3 of FIG. 1.

Next, an operation of the LNA 1 of FIG. 1 will be described. In the gain mode, the bypass signal Byp is at a low level. Therefore, the charge pump circuit 2 stops the charge pump operation. A first bias voltage VB1 of, for example, 0.55 V is supplied to the gate of the first transistor FET1, and a second bias voltage VB2 of, for example, 1.33 V is supplied to the second transistor FET2. In the gain mode, the third transistor FETsw1 and the fifth transistor FETsw3 are turned on, the fourth transistor FETsw2 is turned off, and the sixth transistor FETsw4 is turned off. Therefore, after the high frequency input signal is amplified by the first transistor FET1, the high frequency input signal is further amplified by the second transistor FET2. The second inductor Ld, the first capacitor Cout1, and the first resistor Rout1 make an output matching circuit, and the signal amplified by the second transistor FET2 is output from the second node OUT through the first capacitor Cout1 and the first resistor Rout1.

In the bypass mode, the bypass signal Byp becomes a high level. Therefore, the charge pump circuit 2 starts the charge pump operation. More specifically, the charge pump circuit 2 performs the charge pump operation using the high frequency input signal as a clock signal. In the bypass mode, since the power supply voltage Vdd_Ina is 0 V and the first bias voltage VB1 and the second bias voltage VB2 are 1.5 V, the first transistor FET1 and the second transistor FET2 are turned on, the third transistor FETsw1 and the fifth transistor FETsw3 are turned off, and the fourth transistor FETsw2 and the sixth transistor FETsw4 are turned on. Since the third transistor FETsw1 is turned off, the first transistor FET1 is operated as a MOS capacitor including the second capacitor Cinb, and the MOS capacitor transmits the high frequency input signal to a drain side of the first transistor FET1. That is, the first transistor FET1 transmits the high frequency input signal to a source side of the second transistor FET2 by capacitive coupling including the second capacitor Cinb, in the bypass mode. Capacitance of the second capacitor Cinb is adjusted so that good input matching can be obtained in the bypass mode.

The high frequency input signal transmitted to the drain side of the first transistor FET1 is amplified by the second transistor FET2 and transmitted to a drain side of the second transistor FET2. In the bypass mode, since the sixth transistor FETsw4 is in a turn-on state, the output matching circuit becomes a parallel circuit between the first capacitor Cout1 and the first resistor Rout1 connected to each other in series and the fourth capacitor Cout2 and the sixth transistor FETsw4 connected to each other in series. Since the fourth capacitor Cout2 has capacitance much larger than that of the first capacitor Cout1, the signal is output from the second node OUT mainly through the fourth capacitor Cout2.

In the bypass mode, the charge pump circuit 2 sets the potential of the connection node between the second resistor Rgg1 and the third resistor Rgg2 connected to the gate of the third transistor FETsw1 in series to a negative potential. Therefore, the third transistor FETsw1 is certainly turned off. When the third transistor FETsw1 is certainly turned off, loss of a signal flowing between the drain and the source of the first transistor FET1 can be suppressed, and the first transistor FET1 can be operated as a MOS capacitor.

As described above, according to the LNA 1 of FIG. 1, since the signal loss can be suppressed even when input signal power is increased in the bypass mode, IP1 dB can be improved. That is, IP1 dB can be further increased.

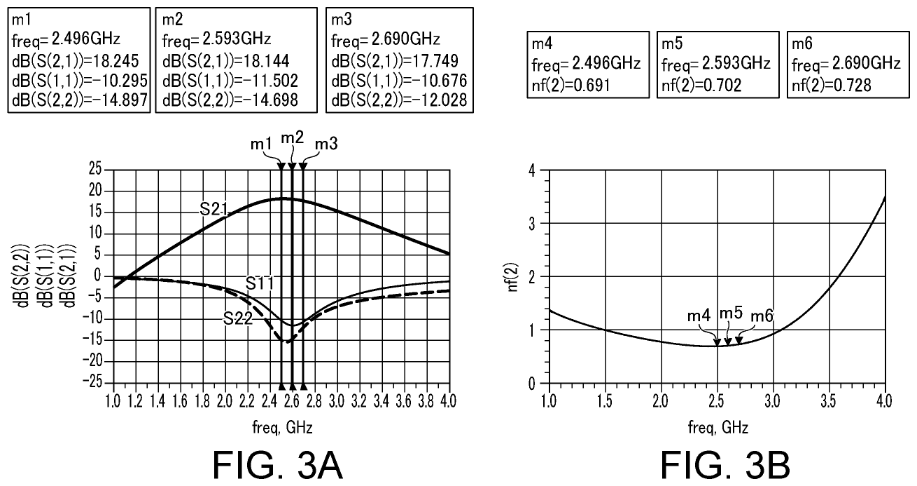

Next, a simulation result of the LNA 1 of FIG. 1 is illustrated. In a simulation, threshold voltages of the third to fifth transistors FETsw1, FETsw2, and FETsw3 were set to 0.3 V. FIGS. 3A and 3B are views illustrating small signal characteristics in the gain mode of the LNA 1 of FIG. 1. More specifically, FIG. 3A illustrates S parameters in the gain mode of the LNA 1 of FIG. 1. A horizontal axis in FIG. 3A is a frequency [GHz], and a vertical axis in FIG. 3A is an S parameter value [dB]. In FIG. 3A, a curve of reflection characteristic S11 of an input side, a curve of reflection characteristic S22 of an output side, and a curve of transmission characteristic S21 from the input side to the output side are illustrated.

FIG. 3B is a view illustrating a noise factor NF in the gain mode of the LNA 1 of FIG. 1. A horizontal axis in FIG. 3B is a frequency [GHz], and a vertical axis in FIG. 3B is a noise factor NF [dB].

In FIGS. 3A and 3B, marks are attached to 2.496 GHz, 2.593 GHz, and 2.690 GHz which are frequency bands of Band41, which is one of long term evolution (LTE) bands. The LNA 1 according to the present embodiment is designed in consideration of the use in the frequency band of Band41, but as can be seen from FIG. 3A, S parameters in the frequency band of Band41 are good. For example, at a band center frequency of 2.593 GHz, a gain is 18.0 dB, S11 is −10 dB or less, and S22 is −12 dB or less, and a generally required reference value is secured. In addition, a noise factor NF of FIG. 3B is also about 0.7 dB, which is a good characteristic.

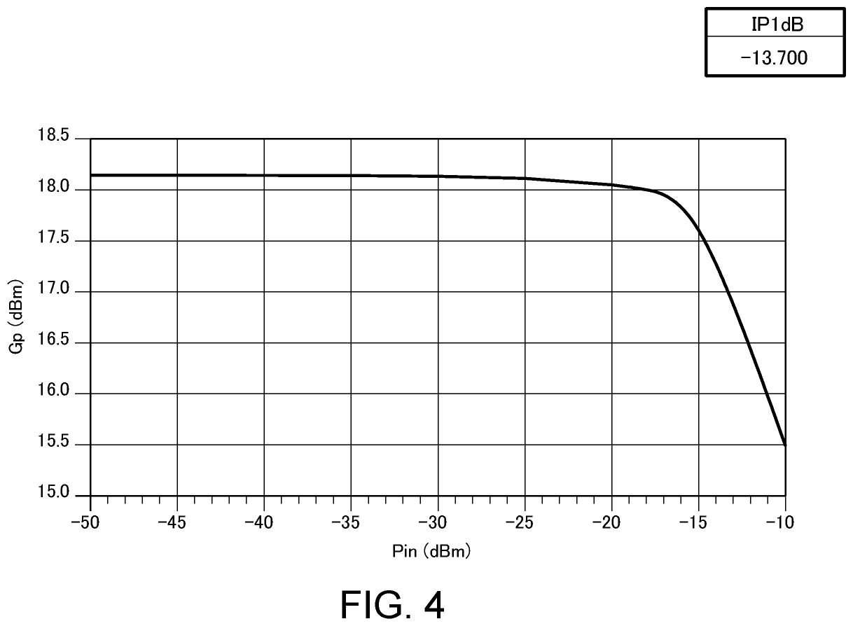

FIG. 4 is a graph illustrating large signal characteristics in the gain mode of the LNA 1 of FIG. 1, and illustrates input power dependency of a gain. A horizontal axis in FIG. 4 is an input signal power Pin [dBm], and a vertical axis in FIG. 4 is a gain Gp [dB]. It can be seen from the graph of FIG. 4 that IP1 dB is −13.7 dBm, which is a good characteristic.

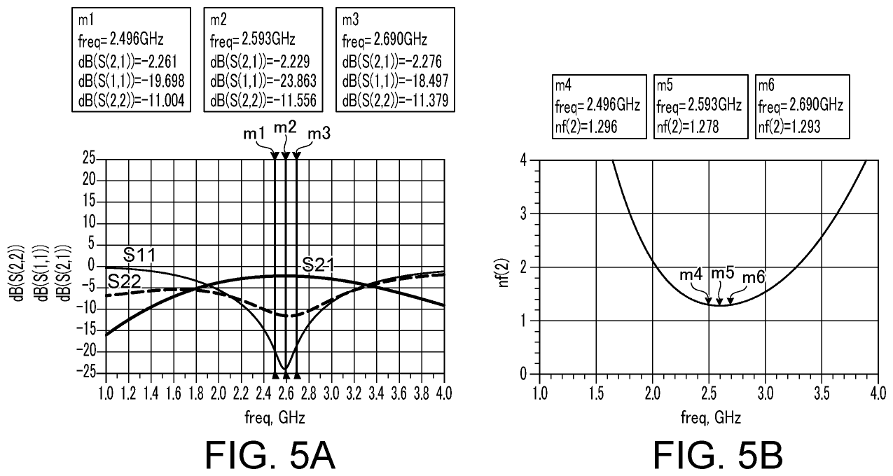

FIGS. 5A and 5B are views illustrating small signal characteristics in the bypass mode of the LNA 1 of FIG. 1. More specifically, FIG. 5A illustrates S parameters in the bypass mode of the LNA 1 of FIG. 1. A horizontal axis in FIG. 5A is a frequency [GHz], and a vertical axis in FIG. 5A is an S parameter value [dB]. In FIG. 5A, a curve of reflection characteristic S11 of an input side, a curve of reflection characteristic S22 of an output side, and a curve of transmission characteristic S21 from the input side to the output side are illustrated.

FIG. 5B is a view illustrating a noise factor NF in the bypass mode of the LNA 1 of FIG. 1. A horizontal axis in FIG. 5B is a frequency [GHz], and a vertical axis in FIG. 5B is a noise factor NF [dB].

It can be seen from FIGS. 5A and 5B that an insertion loss of 3 dB or less, S11 of −18 dB or less, S22 of −11 dB or less, and a noise factor NF of about 1.3 dB can be obtained, which can be said to be good characteristics.

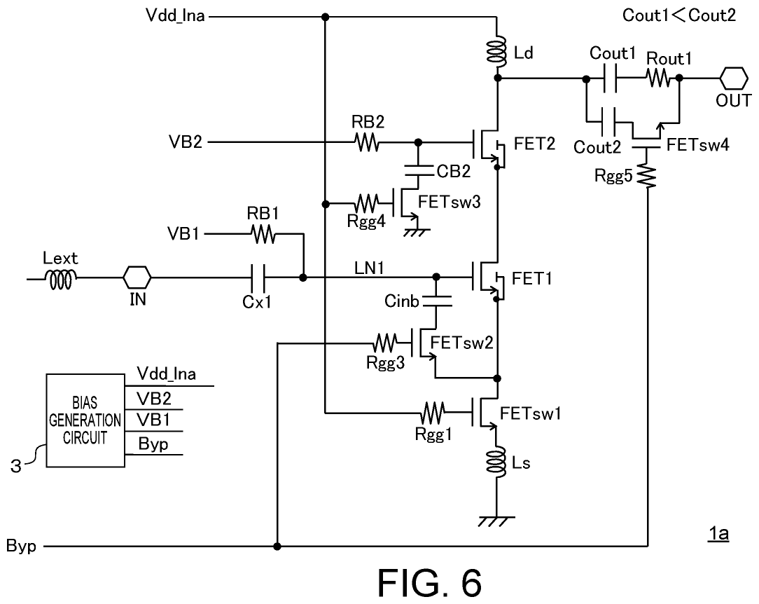

FIG. 6 is a circuit diagram of an LNA 1a according to a comparative example. The LNA 1a of FIG. 6 is obtained by removing the charge pump circuit 2, the second resistor Rgg1, and the first diode Diode3 from the LNA 1 of FIG. 1. The LNA 1a of FIG. 6 has an operation and characteristics similar to those of the LNA 1 of FIG. 1 in the gain mode, but in the bypass mode, the third transistor FETsw1 cannot be certainly turned off, such that there is a possibility that a signal will be leaked to the third transistor FETsw1 through the drain-source of the first transistor FET1. Circuit constants of the LNA 1a of FIG. 6 are the same as those of the LNA 1 of FIG. 1. Small signal characteristics and large signal characteristics in the gain mode and small signal characteristics in the bypass mode of the LNA 1a of FIG. 6 are substantially the same as those of the LNA 1 of FIG. 1.

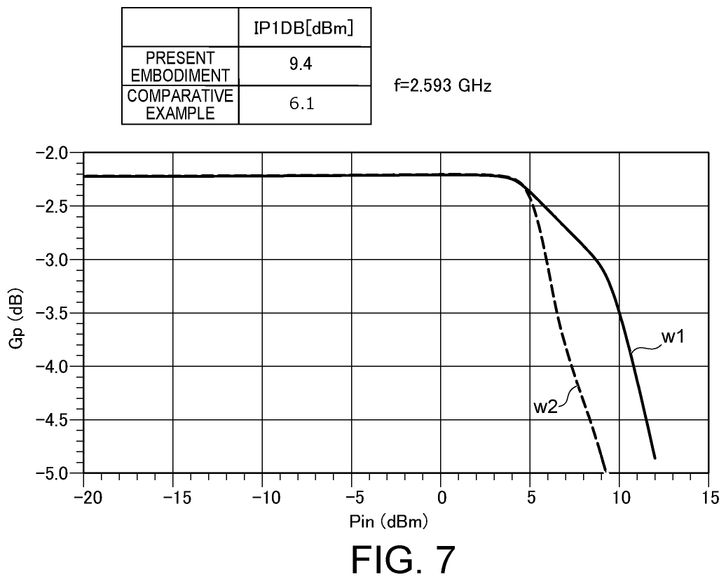

FIG. 7 is a graph illustrating a comparison result between large signal characteristics in the bypass mode of the LNAs 1 and 1a of FIGS. 1 and 6. A horizontal axis in FIG. 7 is an input signal power Pin [dBm], and a vertical axis in FIG. 7 is a gain Gp [dB]. A solid line waveform w1 of FIG. 7 is large signal characteristics of the LNA 1 of FIG. 1, and a broken line waveform w2 of FIG. 7 is large signal characteristics of the LNA 1a of FIG. 6. IP1 dB of the LNA 1a of FIG. 6 is 6.1 dBm, while IP1 dB of the LNA 1 of FIG. 1 is 9.4 dBm, such that an improvement of 3.3 dB can be achieved. In general, IP1 dB in the bypass mode is required to be 8 dBm or more, but the LNA 1 of FIG. 1 satisfies such a requirement.

As described above, in the first embodiment, since the second resistor Rgg1 and the third resistor Rgg2 are connected to each other in series between the gate of the third transistor FETsw1 cascode-connected to the first transistor FET1 and turned off in the bypass mode and the power supply voltage Vdd_Ina node, and the potential of the connection node between the second resistor Rgg1 and the third resistor Rgg2 is set to the negative potential by the charge pump circuit 2, the third transistor FETsw1 can be reliably turned off in the bypass mode. Therefore, even though a high frequency signal of a large power is input in the bypass mode, the signal is not leaked to the third transistor FETsw1 through the drain-source of the first transistor FET1, such that IP1 dB can be improved.

### Second Embodiment

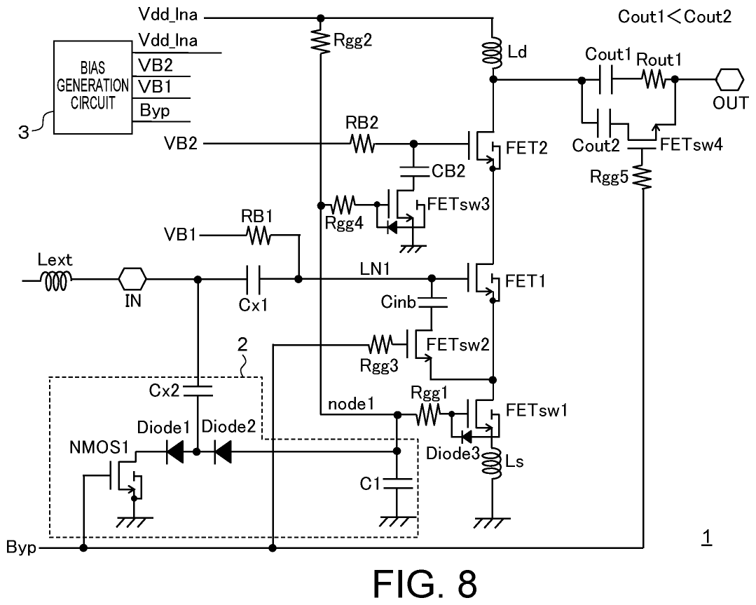

FIG. 8 is a circuit diagram of an LNA 1 according to a second embodiment. The LNA 1 of FIG. 8 has the same circuit configuration as that of the LNA 1 of FIG. 1 except for a connection place of the third resistor Rgg2 of the LNA 1 of FIG. 1. In addition, each voltage and signal generated by a bias generation circuit 3 are similar to those in FIG. 2.

One end of the third resistor Rgg2 in the LNA 1 of FIG. 8 is connected to a power supply voltage Vdd_lna node, and the other end of the third resistor Rgg2 is connected to a second resistor Rgg1 and a seventh resistor Rgg4. A connection node between the third resistor Rgg2 and the second and seventh resistors Rgg1 and Rgg4 is connected to an output node of a charge pump circuit 2. Therefore, when a potential of a lower electrode of a sixth capacitor Cx2 has a negative potential while the charge pump circuit 2 is performing a charge pump operation, a current flows from the power supply voltage Vdd_Ina node to a third diode Diode2 through the third resistor Rgg2. Therefore, a potential of the connection node between the third resistor Rgg2 and the second and seventh resistors Rgg1 and Rgg4 becomes a negative potential, such that a third transistor FETsw1 and a fifth transistor FETsw3 can be certainly turned off. That is, turn-on withstand voltages of the third transistor FETsw1 and the fifth transistor FETsw3 can be improved, and IP1 dB can be further improved as compared with the LNA 1 of FIG. 1. It should be noted that all of the resistance values of each of the second resistor Rgg1, the third resistor Rgg2, and the seventh resistor Rgg4 are, for example, 100 kΩ.

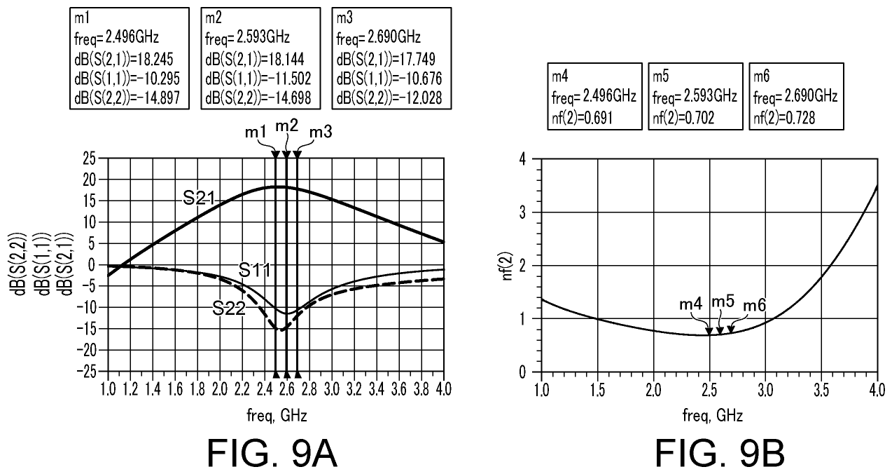

FIGS. 9A and 9B to 12 are views illustrating simulation results of the LNA 1 of FIG. 8. FIGS. 9A and 9B are views illustrating small signal characteristics in a gain mode of the LNA 1 of FIG. 8. A gain of about 18 dB, S11 of −10 dB or less, S22 of −12 dB or less, and a noise factor NF of about 0.7 dB can be obtained, which can be said to be good characteristics.

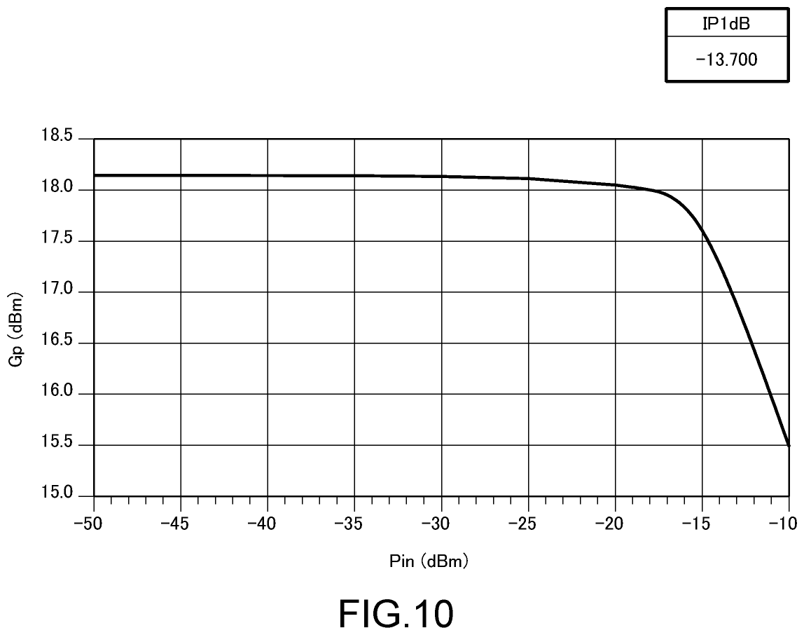

FIG. 10 is a graph illustrating large signal characteristics in the gain mode of the LNA 1 of FIG. 8. IP1 dB is −13.7 dBm, which is good.

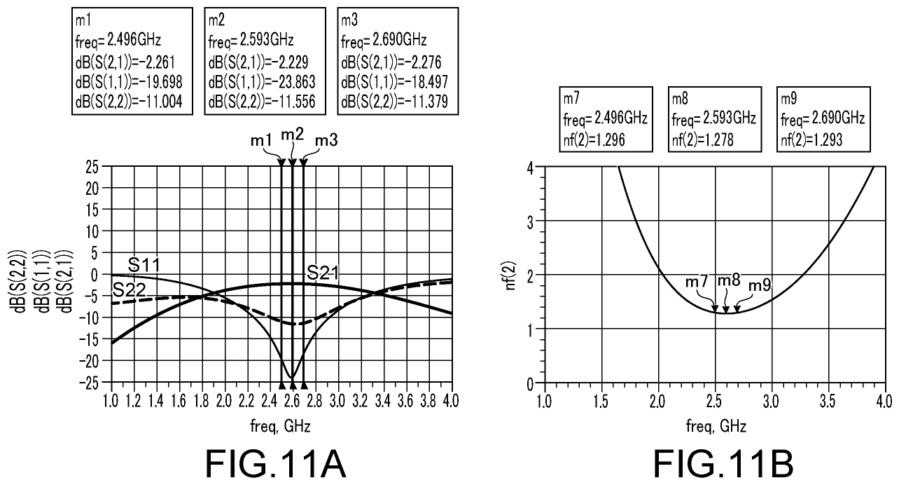

FIGS. 11A and 11B are views illustrating small signal characteristics in a bypass mode of the LNA 1 of FIG. 8. An insertion loss of 3 dB or less, S11 of −18 dB or less, S22 of −11 dB or less, and a noise factor NF of about 1.3 dB can be obtained, which can be said to be good characteristics.

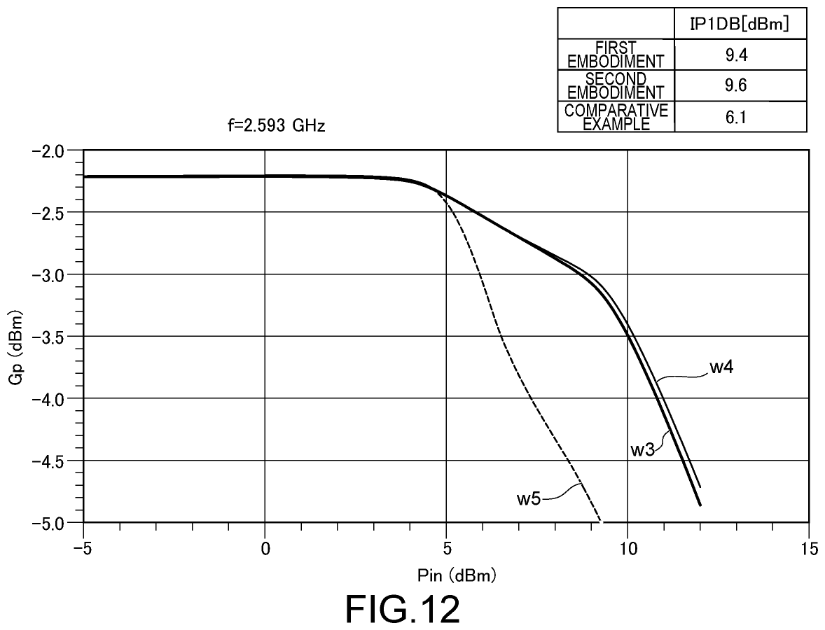

FIG. 12 is a graph illustrating a comparison result among large signal characteristics in the bypass mode of each LNA 1 and 1a of FIGS. 1, 6, and 8. A waveform w3 of FIG. 12 shows large signal characteristics of the LNA 1 of FIG. 1, a waveform w4 of FIG. 12 shows large signal characteristics of the LNA 1 of FIG. 8, and a waveform w5 of FIG. 12 shows large signal characteristics of the LNA 1a of FIG. 6. As illustrated in FIG. 12, IP1 dB of the LNA 1a according to the comparative example of FIG. 6 is 6.1 dBm, while IP1 dB of the LNA 1 of FIG. 8 is 9.6 dBm, which is improved by 3.5 dB as compared with 6.1 dBm. In addition, it can be seen that IP1 dB (=9.6) of the LNA 1 of FIG. 8 is slightly more excellent than IP1 dB (=9.4) of the LNA 1 of FIG. 1.

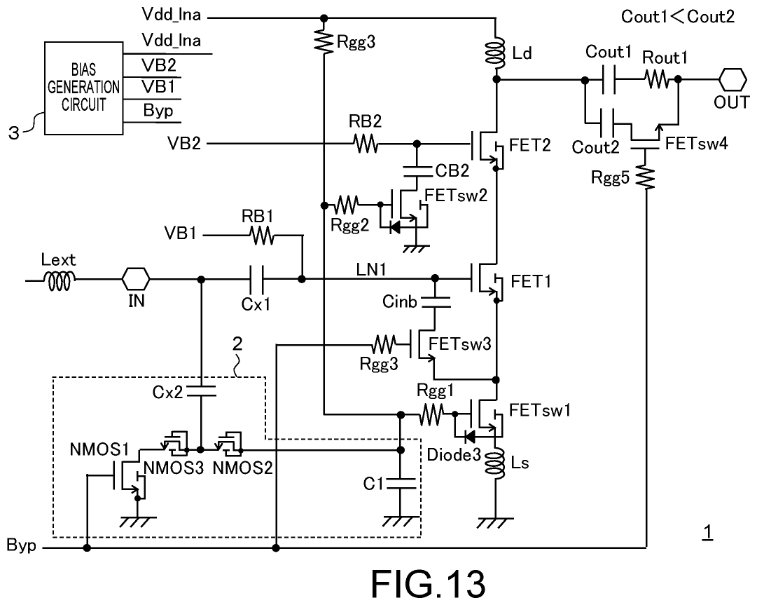

FIG. 13 is a circuit diagram of an LNA 1 according to a modified example of FIG. 8. The LNA 1 of FIG. 13 is obtained by replacing a second diode Diode2 and the third diode Diode1 of FIG. 8 with seventh and eighth transistors NMOS2 and NMOS3 diode-connected to each other. The other circuit configuration is similar to that of the LNA 1 of FIG. 8.

Gates and bodies of the seventh and eighth transistors NMOS2 and NMOS3 are connected to drains thereof. Gate oxide film thicknesses Tox, gate lengths Lg, and threshold voltages Vth of the seventh and eighth transistors NMOS2 and NMOS3 may be similar to those of third to sixth transistors FETsw1 to FETsw4.

According to a simulation of the present inventor, it has been confirmed that the LNA 1 of FIG. 13 can also obtain electrical characteristics similar to those of the LNA 1 of FIG. 8.

As described above, in the second embodiment, since the connection node between the third resistor Rgg2 and the second and seventh resistors Rgg1 and Rgg4 is connected to the output node of the charge pump circuit 2, the potential of the connection node can be set to the negative potential by the charge pump operation, such that the third transistor FETsw1 and the fifth transistor FETsw3 can be reliably turned off in the bypass mode. Therefore, IP1 dB in the bypass mode can be further improved as compared with the LNA 1 according to the first embodiment.

### Third Embodiment

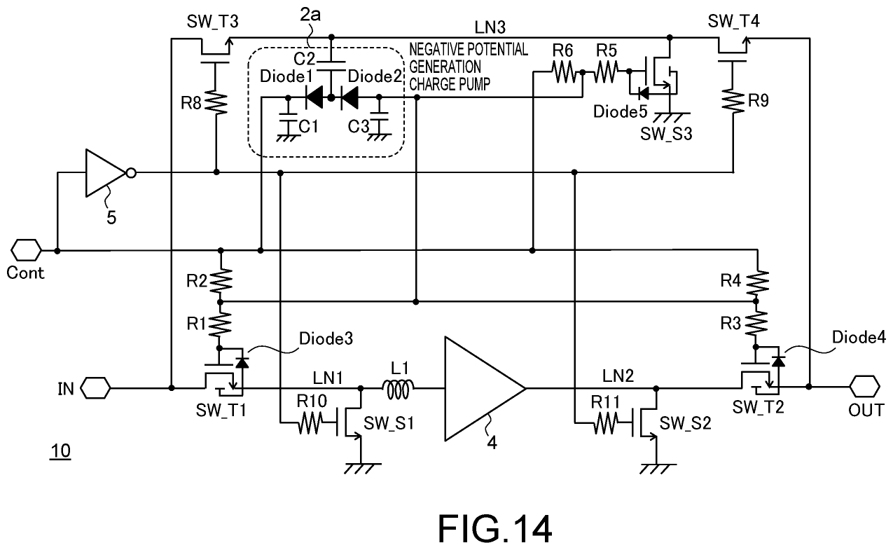

FIG. 14 is a circuit diagram of an LNA 10 according to a third embodiment. The LNA 10 of FIG. 14 includes an amplifier 4, first to fourth transistors SW_T1 to SW_T4, fifth to seventh transistors SW_S1 to SW_S3, first to eleventh resistors R1 to R11, a charge pump circuit 2a, and an inverter 5. The LNA 1 may be configured as illustrated in the entire circuit diagram of FIG. 14 or the LNA1 may be configured by the amplifier 4 of FIG. 14 and the first to seventh transistors SW_T1 to SW_T4 and SW_S1 to SW_S3, the resistors R1 to R6 and R8 to R11, and the charge pump circuit 2a may be provided in the vicinity of the LNA 1.

An input node of the amplifier 4 is connected to an input signal path LN1. A first node IN to which a high frequency input signal is input, the first transistor SW_T1, and a first inductor L1 are connected to each other on the input signal path LN1. The first transistor SW_T1 conducts the input signal path LN1 between the first node IN and the input node of the amplifier 4 in a gain mode, and blocks the input signal path LN1 between the first node IN and the input node of the amplifier 4 in a bypass mode. The first resistor R1 and the second resistor R2 are connected to each other in series between a gate of the first transistor SW_T1 and a control signal node Cont to which a control signal is input.

An output node of the amplifier 4 is connected to an output signal path LN2. The second transistor SW_T2 and a second node OUT outputting an output signal of the LNA 10 are connected to each other on the output signal path LN2. The second transistor SW_T2 conducts the output signal path LN2 between the output node of the amplifier 4 and the second node OUT in the gain mode, and blocks the output signal path LN2 between the output node of the amplifier 4 and the second node OUT in a second mode. The third resistor R3 and the fourth resistor R4 are connected to each other in series between the second transistor SW_T2 and the control signal node Cont.

The LNA 10 of FIG. 14 includes a bypass signal path LN3, separately from the input signal path LN1 and the output signal path LN2. The third transistor SW_T3 and the fourth transistor SW_T4 are cascode-connected to each other on the bypass signal path LN3. The bypass signal path LN3 is a path through which the high frequency input signal is transmitted from the input signal path LN1 to the second node OUT without passing through the amplifier 4 in the bypass mode.

The third transistor SW_T3 and the fourth transistor SW_T4 block the bypass signal path LN3 in the gain mode and conduct the bypass signal path LN3 in the bypass mode. The eighth resistor R8 is connected between a gate of the third transistor SW_T3 and an output node of the inverter 5 inverting the control signal. In addition, the ninth resistor R9 is connected between a gate of the fourth transistor SW_T4 and the output node of the inverter 5.

The fifth transistor SW_S1 chooses whether or not to short-circuit the input signal path LN1 to a ground node (first reference potential node). The tenth resistor R10 is connected between a gate of the fifth transistor SW_S1 and the output node of the inverter 5.

The sixth transistor SW_S2 chooses whether or not to short-circuit the output signal path LN2 to a ground node. The eleventh resistor R11 is connected between a gate of the sixth transistor SW_S2 and the output node of the inverter 5.

The seventh transistor SW_S3 chooses whether or not to short-circuit the bypass signal path LN3 to a ground node. The fifth resistor R5 and the sixth resistor R6 are connected to each other in series between a gate of the seventh transistor SW_S3 and the control signal node Cont.

An input node of the charge pump circuit 2a is connected onto the bypass signal path LN3, that is, between a source of the third transistor SW_T3 and a drain of the fourth transistor SW_T4. An output node of the charge pump circuit 2a is connected to a connection node between the first resistor R1 and the second resistor R2, a connection node between the third resistor R3 and the fourth resistor R4, and a connection node between the fifth resistor R5 and the sixth resistor R6.

The charge pump circuit 2a includes first and second diodes Diode1 and Diode2, and first to third capacitors C1 to C3. The first capacitor C1 is connected between the control signal node Cont and a ground node. A cathode of the second diode Diode2 is connected to an anode of the first diode Diode1. A cathode of the first diode Diode1 is connected to the control signal node Cont. The second capacitor C2 is connected between the bypass signal path LN3 and the anode of the first diode Diode1. The third capacitor C3 is connected between an anode of the second diode Diode2 and a ground node.

The charge pump circuit 2a performs a charge pump operation of causing a current to flow by a path returning from the control signal node Cont of a ground potential to the ground potential through the second resistor R2, a path returning from the control signal node Cont to the ground potential through the fourth resistor R4, and a path from the control signal node Cont to the ground potential through the sixth resistor R6 in the bypass mode, and stops the charge pump operation in the gain mode.

Next, an operation of the LNA 10 of FIG. 14 will be described. In the gain mode, the control signal input to the control signal node Cont becomes a high level. In this case, since an output of the inverter 5 becomes a low level, both of the third transistor SW_T3 and the fourth transistor SW_T4 are turned off, and the bypass signal path LN3 is blocked. In the gain mode, the charge pump circuit 2a also stops the charge pump operation. In addition, in the gain mode, the seventh transistor SW_S3 is turned on. In the gain mode, a K factor should not be less than 1 to prevent oscillation of the LNA 10 of FIG. 14. In order to make the K factor 1 or more, it is preferable to turn on the seventh transistor SW_S3 to short-circuit the bypass signal path LN3 to the ground node.

In the gain mode, the first transistor SW_T1 and the second transistor SW_T2 are turned on together, and the fifth transistor SW_S1 and the sixth transistor SW_S2 are turned off together. For this reason, the high frequency input signal input to the first node IN is input to the amplifier 4 through the first transistor SW_T1 and the first inductor L1. The amplifier 4 includes, for example, a source-grounded FET and a gate-grounded FET (not illustrated in FIG. 14) cascode-connected to each other, and amplifies and outputs the high frequency input signal input to the gate-grounded FET. The signal output from the amplifier 4 is output from the second node OUT through the second transistor SW_T2.

Meanwhile, in the bypass mode, the control signal becomes a low level. Therefore, the first transistor SW_T1 and the second transistor SW_T2 are turned off together, and the fifth transistor SW_S1 and the sixth transistor SW_S2 are turned on together.

The reason for turning on the fifth transistor SW_S1 is that, in the bypass mode, turn-off capacitance of the first transistor SW_T1 is large, the input of the amplifier 4 is also capacitive, and LC resonance occurs between these pieces of capacitance and the first inductor L1, such that there is a possibility that a drop in a gain will occur at a certain frequency. For this reason, in the bypass mode, LC resonance on the input signal path LN1 can be prevented by turning on the fifth transistor SW_S1.

In addition, a reason for turning on the sixth transistor SW_S2 is that there is a second inductor Ld similar to that of the LNA 1 of FIG. 1 inside the amplifier 4, and there is a possibility that LC resonance will occur between the second inductor Ld and turn-off capacitance of the second transistor SW_T2. For this reason, in the bypass mode, LC resonance on the output signal path LN2 can be prevented by turning on the sixth transistor SW_S2.

In addition, in the bypass mode, the third transistor SW_T3 and the fourth transistor SW_T4 are turned on together, and the seventh transistor SW_S3 is turned off. In the bypass mode, the cathode of the first diode Diode1 in the charge pump circuit 2a is at a ground level, and the charge pump operation is thus performed. The charge pump circuit 2a performs the charge pump operation using the high frequency input signal transmitted from the first node IN to the bypass signal path LN3 through the third transistor SW_T3 as a clock signal. The charge pump circuit 2a performs the charge pump operation, such that potentials of the connection node between the first resistor R1 and the second resistor R2, the connection node between the third resistor R3 and the fourth resistor R4, and the connection node between the fifth resistor R5 and the sixth resistor R6 can be set to a negative potential. Therefore, in the bypass mode, the first transistor SW_T1, the second transistor SW_T2, and the seventh transistor SW_S3 can be certainly turned off, such that there is no possibility that a signal is leaked from the input signal path LN1 to the output signal path LN2 through the amplifier 4, and IP1 dB can thus be improved.

A PN junction diode whose body is an anode and gate is a cathode is connected between a body and a gate of each of the first transistor SW_T1, the second transistor SW_T2, and the seventh transistor SW_S3. This PN junction diode is for improving a drain withstand voltage when the gate of each of these transistors is at a negative potential.

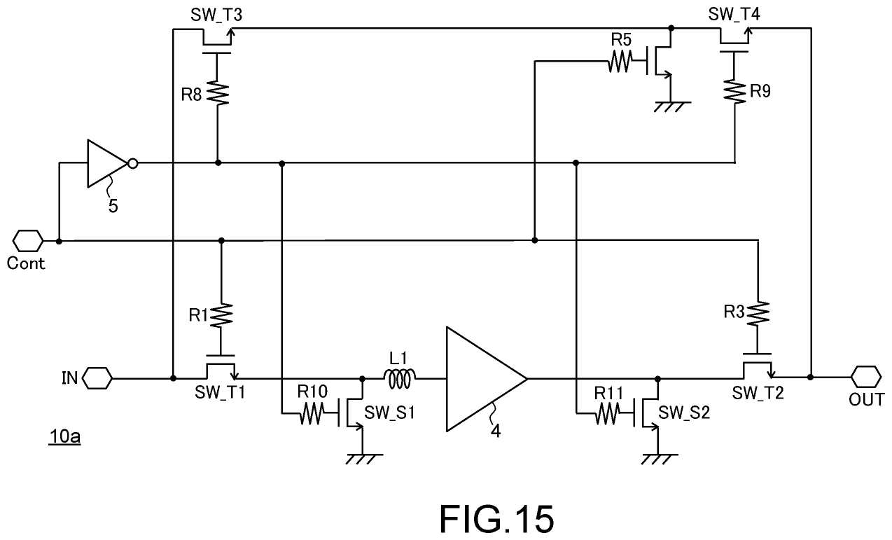

FIG. 15 is a circuit diagram of an LNA 10 according to a comparative example of FIG. 14. The LNA 10 of FIG. 15 is obtained by omitting the charge pump circuit 2a, the second resistor R2, the fourth resistor R4, and the sixth resistor R6 from the LNA 10 of FIG. 14.

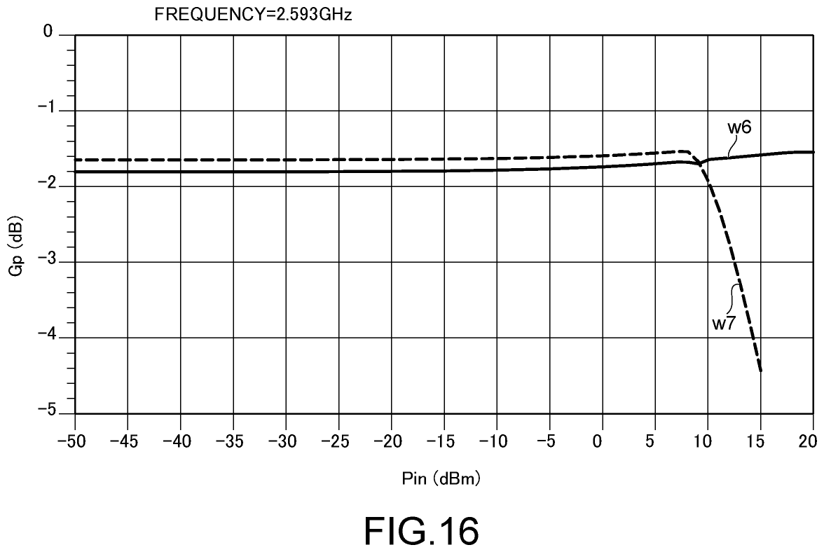

FIG. 16 is a graph illustrating simulation results of the LNAs 10 of FIGS. 14 and 15. A horizontal axis in FIG. 16 is an input signal power Pin [dBm], and a vertical axis in FIG. 16 is a gain Gp [dB]. The graph of FIG. 16 illustrates input signal power dependency of a gain in the bypass mode, a solid line waveform w6 illustrates the LNA 10 of FIG. 14, and a broken line waveform w7 illustrates the LNA 10 according to the comparative example of FIG. 15. In the graph of FIG. 16, the LNA is considered to be used in a frequency band of Band41 at a threshold voltage Vth=0.4 V of the first to seventh transistors SW_T1 to SW_T4 and SW_S1 to SW_S3. It can be seen from the graph of FIG. 16 that IP1 dB of the LNA 10 of FIG. 14 exceeds 20 dBm, while IP1 dB of the LNA 10 according to the comparative example of FIG. 15 is 11.1 dBm.

As described above, in the third embodiment, the bypass signal path LN3 is provided separately from the input signal path LN1 and the output signal path LN2 of the amplifier 4, and the LNA includes the first transistor SW_T1 that chooses whether or not to block the input signal path LN1, the second transistor SW_T2 that chooses whether or not to block the output signal path LN2, and the third transistor SW_T3 and the fourth transistor SW_T4 that chooses whether or not to block the bypass signal path LN3. In addition, the charge pump circuit 2a is connected onto the bypass signal path LN3, and the output node of the charge pump circuit 2a is connected to the connection node between the first resistor R1 and the second resistor R2 connected to the gate of the first transistor SW_T1 in series, the connection node between the third resistor R3 and the fourth resistor R4 connected to the gate of the second transistor SW_T2 in series, and the connection node between the fifth resistor R5 and the sixth resistor R6 connected to the gate of the seventh transistor SW_S3 in series. Therefore, in the bypass mode, the charge pump circuit 2a performs the charge pump operation, such that the potentials of the connection node between the first resistor R1 and the second resistor R2, the connection node between the third resistor R3 and the fourth resistor R4, and the connection node between the fifth resistor R5 and the sixth resistor R6 can be set to the negative potential. As a result, the input signal path LN1 and the output signal path LN2 can be blocked, and IP1 dB can thus be improved.

### Fourth Embodiment

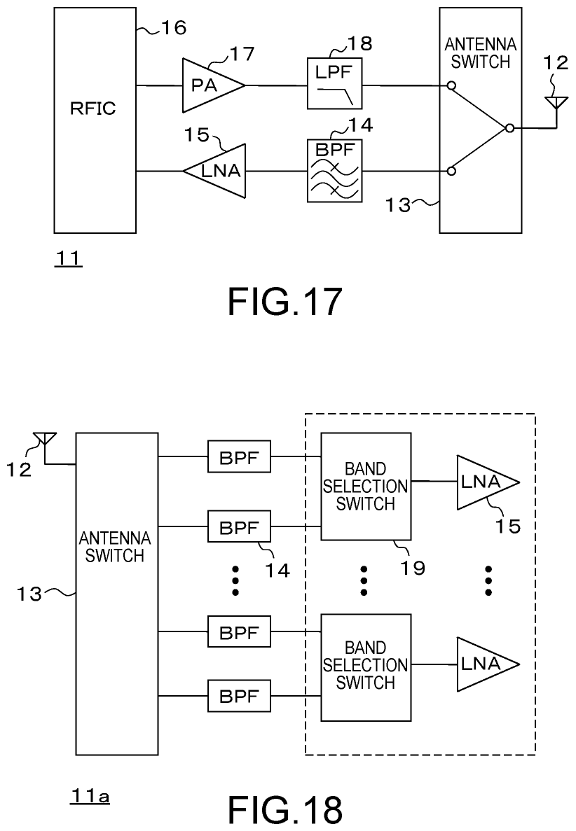

FIG. 17 is a block diagram illustrating a schematic configuration of a wireless device 11 in which the LNA 1 or the LNA 10 according to the first to third embodiments is embedded. The wireless device 11 of FIG. 17 includes an antenna 12, an antenna switch 13, a band pass filter (BPF) 14, an LNA 15, a radio frequency integrated circuit (RFIC) 16, a power amplifier (PA) 17, and a low pass filter (LPF) 18.

The LNA 15 of FIG. 17 has a circuit configuration similar to that of the LNA 1 according to the first or second embodiment or the LNA 10 according to the third embodiment.

The antenna switch 13 is a switch switching transmission and reception. A transmit side and a receive side each show an example of one system in FIG. 1, but the transmit side and the receive side may each have a plurality of systems transmitting and receiving signals of a plurality of frequency bands. The antenna switch 13 and the LNA 15 of FIG. 17 can be disposed on the same SOI substrate, such that they can be realized in a single chip. By disposing the antenna switch 13 and the LNA 15 on the SOI substrate, it is possible to reduce power consumption and miniaturize the wireless device.

In recent mobile communication devices, wireless communication is often performed using a carrier aggregation technology in which wireless communication is performed using a plurality of frequencies. In this case, it is necessary to dispose a plurality of LNAs 15 and a plurality of band switching switches on the SOI substrate. FIG. 18 is a block diagram illustrating a schematic configuration of a wireless device 11a corresponding to carrier aggregation. FIG. 18 illustrates a block configuration of a receiving circuit from an antenna 12. A block configuration of a transmitting circuit is similar to that illustrated in FIG. 17.

The wireless device 11a in FIG. 18 includes an antenna switch 13, a plurality of band pass filters 14, a plurality of band selection switches 19, and a plurality of LNAs 15. The plurality of band selection switches 19 and the plurality of LNAs 15 are disposed on the same SOI substrate, such that they can be realized in a single chip. Alternatively, the antenna switch 13 as well as the plurality of band selection switches 19 and the plurality of LNAs 15 may be disposed on the same SOI substrate, such that they can be realized in a single chip.

Each of the plurality of LNAs 15 of FIG. 18 may be the LNA 1 according to the first or second embodiment or the LNA 10 according to the third embodiment. A received signal of each frequency switched by the antenna switch 13 passes through the corresponding band pass filter 14 and is then input to the corresponding band selection switch 19. The input signal selected by the band selection switch 19 is input to and amplified in the corresponding LNA 15 or bypasses the corresponding LNA 15.

By disposing the plurality of band selection switches 19 and the plurality of LNAs 15 on the SOI substrate, it is possible to miniaturize the wireless device and reduce power consumption.

An example in which the LNA 1 or the LNA 10 is disposed on the SOI substrate has been described in the first to third embodiments described above, but the LNA 1 or the LNA 10 according to the first to third embodiments may be disposed on a bulk silicon substrate. Also in the LNA 1 or the LNA 10 disposed on the bulk silicon substrate, IP1 dB can be improved by adopting the circuit configurations according to the embodiments described above.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A low noise amplifier comprising:
a first transistor that amplifies a high frequency input signal and has a grounded source;
a second transistor that further amplifies the signal amplified by the first transistor to generate an output signal and has a grounded gate;
a first inductor that is connected between the source of the first transistor and a first reference potential node;
a third transistor that is connected between the source of the first transistor and the first inductor, is turned on in a first mode, and is turned off in a second mode;
a first capacitor and a first resistor that are connected to each other in series between a drain of the second transistor and an output node of the low noise amplifier;
a second resistor and a third resistor that are connected to each other in series between a gate of the third transistor and a second reference potential node; and
a charge pump circuit that sets a potential of a connection node between the second resistor and the third resistor to a potential lower than a potential of the first reference potential node in the second mode.

2. The low noise amplifier according to claim 1, further comprising:
a second inductor that is connected between the drain of the second transistor and the second reference potential node;
a second capacitor that is connected between a gate of the first transistor and the source of the first transistor;
a fourth transistor that is connected to the second capacitor between the gate of the first transistor and the source of the first transistor in series, is turned off in the first mode, and is turned on in the second mode;
a third capacitor that is connected between the gate of the second transistor and the first reference potential node; and
a fifth transistor that is connected to the third capacitor between the gate of the second transistor and the first reference potential node in series, is turned on in the first mode, and is turned off in the second mode.

3. The low noise amplifier according to claim 1, further comprising
a fourth capacitor and a sixth transistor that are connected to the first capacitor and the first resistor in parallel,
wherein the first capacitor has smaller capacitance than capacitance of the fourth capacitor, and
the sixth transistor is set to be turned off in the first mode and is set to be turned on in the second mode.

4. The low noise amplifier according to claim 2,
wherein the first transistor transmits the high frequency input signal to a source side of the second transistor by capacitive coupling including the second capacitor in the second mode.

5. The low noise amplifier according to claim 2, further comprising
a fourth resistor that is connected between a gate of the fifth transistor and the connection node between the second resistor and the third resistor.

6. The low noise amplifier according to claim 5,
wherein one end of the third resistor is connected to the second reference potential node, and the other end of the third resistor is connected to one end of the second resistor, one end of the fourth resistor, and an output node of the charge pump circuit,
the other end of the second resistor is connected to the gate of the third transistor, and
the other end of the fourth resistor is connected to a gate of the fifth transistor.

7. The low noise amplifier according to claim 1, further comprising
a diode that has an anode connected to a body of the third transistor and a cathode connected to the gate of the third transistor.

8. The low noise amplifier according to claim 1,
wherein the first mode is a mode for amplifying the high frequency input signal, and
the second mode is a mode for causing the high frequency input signal to bypass the low noise amplifier without amplifying the high frequency input signal.

9. The low noise amplifier according to claim 1,
wherein the first to third transistors are N-type metal oxide semiconductor (MOS) transistors.

10. A low noise amplifier comprising:
an amplifier that amplifies a high frequency input signal;
a first transistor that conducts an input signal path between a first node to which the high frequency input signal is input and an input node of the amplifier in a first mode and blocks the input signal path between the first node and the input node of the amplifier in a second mode;
a second transistor that conducts an output signal path between an output node of the amplifier and a second node outputting an output signal of the low noise amplifier in the first mode and blocks the output signal path between the output node of the amplifier and the second node in the second mode;
a third transistor and a fourth transistor that block a bypass signal path through which the high frequency input signal bypasses the amplifier from the input signal path to the second node without passing through the amplifier in the first mode and conduct the bypass signal path in the second mode;
a first resistor and a second resistor that are connected to each other in series between a gate of the first transistor and a control signal node to which a control signal switching and controlling turn-on or turn-off of the first transistor is input;
a third resistor and a fourth resistor that are connected to each other in series between a gate of the second transistor and the control signal node; and
a charge pump circuit that sets potentials of a connection node between the first resistor and the second resistor and a connection node between the third resistor and the fourth resistor to be lower than a potential of a first reference potential node, in the second mode.

11. The low noise amplifier according to claim 10,
wherein the charge pump circuit performs a charge pump operation of causing a current to flow by a path returning from the control signal node to the control signal node through the second resistor and a path returning from the control signal node to the control signal node through the fourth resistor in the second mode and stops the charge pump operation in the first mode.

12. The low noise amplifier according to claim 10, further comprising:
a fifth transistor that chooses whether or not to short-circuit the input signal path to a first reference potential node;
a sixth transistor that chooses whether or not to short-circuit the output signal path to the first reference potential node;
a seventh transistor that chooses whether or not to short-circuit the bypass signal path to the first reference potential node; and
a fifth resistor and a sixth resistor that are connected to each other in series between a gate of the seventh transistor and the control signal node,
wherein the charge pump circuit sets potentials of the connection node between the first resistor and the second resistor, the connection node between the third resistor and the fourth resistor, and a connection node between the fifth resistor and the sixth resistor to be lower than the potential of the first reference potential node, in the second mode.

13. The low noise amplifier according to claim 12,
wherein the charge pump circuit performs a charge pump operation of causing a current to flow by a path returning from the control signal node to the control signal node through the second resistor, a path returning from the control signal node to the control signal node through the fourth resistor, and a path returning from the control signal node to the control signal node through the sixth resistor in the second mode and stops the charge pump operation in the first mode.

14. The low noise amplifier according to claim 10,
wherein the first mode is a mode for amplifying the high frequency input signal, and
the second mode is a mode for causing the high frequency input signal to bypass the low noise amplifier without amplifying the high frequency input signal.

15. The low noise amplifier according to claim 10,
wherein the first to fourth transistors are N-type MOS transistors.

16. A semiconductor device comprising:
a plurality of low noise amplifiers that are disposed on a silicon on insulator (SOI) substrate; and
a plurality of high frequency switches that are disposed on the SOI substrate so as to correspond to the plurality of low noise amplifiers, respectively, select one of a plurality of high frequency signals, and supply the selected high frequency signal to a corresponding low noise amplifier,
wherein at least one of the plurality of low noise amplifiers comprises:
a first transistor that amplifies a high frequency input signal and has a grounded source;
a second transistor that further amplifies the signal amplified by the first transistor to generate an output signal and has a grounded gate;
a first inductor that is connected between the source of the first transistor and a first reference potential node;
a third transistor that is connected between the source of the first transistor and the first inductor, is turned on in a first mode, and is turned off in a second mode;
a first capacitor and a first resistor that are connected to each other in series between a connection node between a drain of the second transistor and a second inductor and an output node of the corresponding low noise amplifier;
a second resistor and a third resistor that are connected to each other in series between a gate of the third transistor and a second reference potential node; and
a charge pump circuit that sets a potential of a connection node between the second resistor and the third resistor to a potential lower than a potential of the first reference potential node in the second mode.

17. The semiconductor device according to claim 16, further comprising:
a second inductor that is connected between the drain of the second transistor and the second reference potential node;
a second capacitor that is connected between a gate of the first transistor and the source of the first transistor;
a fourth transistor that is connected to the second capacitor between the gate of the first transistor and the source of the first transistor in series, is turned off in the first mode, and is turned on in the second mode;
a third capacitor that is connected between the gate of the second transistor and the first reference potential node; and
a fifth transistor that is connected to the third capacitor between the gate of the second transistor and the first reference potential node in series, is turned on in the first mode, and is turned off in the second mode.

18. The semiconductor device according to claim 16, further comprising
a fourth capacitor and a sixth transistor that are connected to the first capacitor and the first resistor in parallel,
wherein the first capacitor has smaller capacitance than capacitance of the fourth capacitor, and
the sixth transistor is set to be turned off in the first mode and is set to be turned on in the second mode.

19. The semiconductor device according to claim 17,
wherein the first transistor transmits the high frequency input signal to a source side of the second transistor by capacitive coupling including the second capacitor in the second mode.

20. The semiconductor device according to claim 17, further comprising
a fourth resistor that is connected between a gate of the fifth transistor and the connection node between the second resistor and the third resistor.
